(19) United States
(12) Patent Application Publication
(10) Pub. No.: US 2014/0099785 A1
(43) Pub. Date: Apr. 10, 2014

(54) Sacrificial Low Work Function Cap Layer

(71) Applicant: INTERMOLECULAR, INC., San Jose, CA (US)

(72) Inventors: Salil Mujumdar, San Jose, CA (US); Amol Joshi, Sunnyvale, CA (US)

(73) Assignee: Intermolecular, Inc., San Jose, CA (US)

(21) Appl. No.: 13/645,259

(22) Filed: Oct. 4, 2012

(51) Int. Cl. H01L 21/02

(52) U.S. Cl. CPC H01L 21/02697
USPC 438/591

(57) ABSTRACT

A method includes forming an interlayer on a substrate, depositing a dielectric on the interlayer to form a dielectric stack, forming a sacrificial cap layer over the dielectric stack, processing the substrate to alter properties of the dielectric stack, and removing the sacrificial cap layer.

### BACKGROUND

State of the art metal-oxide-semiconductor (MOS) gate stacks employ high-k gate dielectrics, in order to enable equivalent oxide thickness (EOT) scaling, and are created on a semiconductor substrate through a number of processing steps. Such processes often include at least one annealing process. The annealing process introduces oxygen vacancies within the dielectric stack of the devices, which contributes to flat band voltage (V_{fb}) roll-off (RO).

Conventional methods for limiting or reducing oxygen vacancies include low-temperature oxygen annealing (LTOA) processes. LTOA may result in an increase in equivalent oxide thickness (EOT) of a MOS gate stack, and thus, contributes to an increase in operating voltage of the MOS stack and reduced device capability. As such, integrating LTOA processes to decrease oxygen vacancies requires careful optimization of process flows, increases cycle-time, and may result in degraded EOT.

Another conventional approach includes metal ion implantation within the MOS gate stack to limit, or counter, the effect of oxygen vacancies on the flat-band voltage. However, if creating complementary MOS (CMOS) circuitry or both p-channel MOS (PMOS) and n-channel MOS (NMOS) devices, the metal ions necessary for each type of device differs. This results in a significant modification of the process flow. Furthermore, for the desired range of EOT values, the metal ion implantation approach doesn't provide a significant advantage in terms of effective work function (EWF) tuning. Additionally, the peak channel mobility is known to degrade in devices with intentional metal ion implantation due to the formation of dipoles within the dielectric stack of those devices.

### SUMMARY

In some embodiments, a method includes forming an interlayer on a substrate, depositing a dielectric on the interlayer to form a dielectric stack, forming a sacrificial cap layer over the dielectric stack, processing the substrate to alter properties of the dielectric stack, and removing the sacrificial cap layer.

In some embodiments, a method includes preparing a substrate for combinatorial processing, forming an interlayer on a first portion of the substrate, depositing a dielectric on the interlayer to form a dielectric stack, forming a sacrificial cap layer over the dielectric stack, processing the substrate to alter properties of the dielectric stack, and removing the sacrificial cap layer.

These and further aspects of the invention are described more fully below.

### BRIEF DESCRIPTION OF THE DRAWINGS

FIG. 1 illustrates a simplified schematic diagram providing an overview of the High-Productivity Combinatorial (HPC) screening process for use in evaluating materials, unit processes, and process sequences for the manufacturing of semiconductor devices in accordance with some embodiments.

FIG. 2 illustrates a flowchart of a general methodology for combinatorial process sequence integration that includes site-isolated processing and/or conventional processing in accordance with some embodiments.

FIG. 3 illustrates a portion of a method of forming a metal-oxide-semiconductor (MOS) gate stack, according to some embodiments.

FIG. 4 illustrates a portion of a method of forming a metal-oxide-semiconductor (MOS) gate stack, according to some embodiments.

FIG. 5 illustrates a portion of a method of forming a metal-oxide-semiconductor (MOS) gate stack, according to some embodiments.

FIG. 6 illustrates a portion of a method of forming a metal-oxide-semiconductor (MOS) gate stack, according to some embodiments.

FIG. 7 illustrates a portion of a method of forming a metal-oxide-semiconductor (MOS) gate stack, according to some embodiments.

FIG. 8 illustrates a portion of a method of forming a metal-oxide-semiconductor (MOS) gate stack, according to some embodiments.

### DETAILED DESCRIPTION

The following description is provided as an enabling teaching of the invention and its best, currently known embodiments. Those skilled in the relevant art will recognize that many changes can be made to the embodiments described, while still obtaining the beneficial results. It will also be apparent that some of the desired benefits of the embodiments described can be obtained by selecting some of the features of the embodiments without utilizing other features. Accordingly, those who work in the art will recognize that many modifications and adaptations to the embodiments described are possible and may even be desirable in certain circumstances, and are a part of the invention. Thus, the following description is provided as illustrative of the principles of the embodiments of the invention and not in limitation thereof, since the scope of the invention is defined by the claims.

It will be obvious, however, to one skilled in the art, that the embodiments described may be practiced without some or all of these specific details. In other instances, well known process operations have not been described in detail in order not to unnecessarily obscure the present invention.

The embodiments describe methods for the formation of a metal-oxide-semiconductor (MOS) gate stack with reduced oxygen vacancies with minimal modification of the conventional process flow, as opposed to conventional flat-band voltage tuning techniques. The method may be integrated with any number of semiconductor manufacturing steps to produce any number of MOS-based devices. As noted below, the embodiments described below may be integrated with combinatorial processing techniques described below.

Semiconductor manufacturing typically includes a series of processing steps such as cleaning, surface preparation, deposition, patterning, etching, thermal annealing, and other related unit processing steps. The precise sequencing and integration of the unit processing steps enables the formation of functional devices meeting desired performance metrics such as efficiency, power production, and reliability.

As part of the discovery, optimization and qualification of each unit process, it is desirable to be able to (i) test different materials, (ii) test different processing conditions within each unit process module, (iii) test different sequencing and integration of processing modules within an integrated processing tool, (iv) test different sequencing of processing tools in executing different process sequence integration flows, and combinations thereof in the manufacture of devices such as integrated circuits. In particular, there is a need to be able to test (i) more than one material, (ii) more than one processing condition, (iii) more than one sequence of processing conditions, (iv) more than one process sequence integration flow, and combinations thereof, collectively known as “combinatorial process sequence integration,” on a single monolithic substrate without the need for consuming the equivalent number of monolithic substrates per materials, processing conditions, sequences of processing conditions, sequences of processes, and combinations thereof. This can greatly improve both the speed and reduce the costs associated with the discovery, implementation, optimization, and qualification of materials, processes, and process integration sequences required for manufacturing.

High Productivity Combinatorial (HPC) processing techniques have been successfully adapted to wet chemical processing such as etching and cleaning HPC processing techniques have also been successfully adapted to deposition processes such as physical vapor deposition (PVD), atomic layer deposition (ALD), and chemical vapor deposition (CVD).

Systems and methods for HPC processing are described in U.S. Pat. No. 7,544,574, filed on Feb. 10, 2006; U.S. Pat. No. 7,824,935, filed on Jul. 2, 2008; U.S. Pat. No. 7,871,928, filed on May 4, 2009; U.S. Pat. No. 7,902,063, filed on Feb. 10, 2006; and U.S. Pat. No. 7,947,531, filed on Aug. 28, 2009 each of which is incorporated by reference herein. Systems and methods for HPC processing are further described in U.S. patent application Ser. No. 11/352,077, filed on Feb. 10, 2006; U.S. patent application Ser. No. 11/419,174, filed on May 18, 2006; U.S. patent application Ser. No. 11/674,132, filed on Feb. 12, 2007; and U.S. patent application Ser. No. 11/674,137, filed on Feb. 12, 2007. The aforementioned patent applications claim priority from provisional patent application 60/725,186 filed Oct. 11, 2005. Each of the aforementioned patent applications and the provisional patent application are incorporated by reference herein.

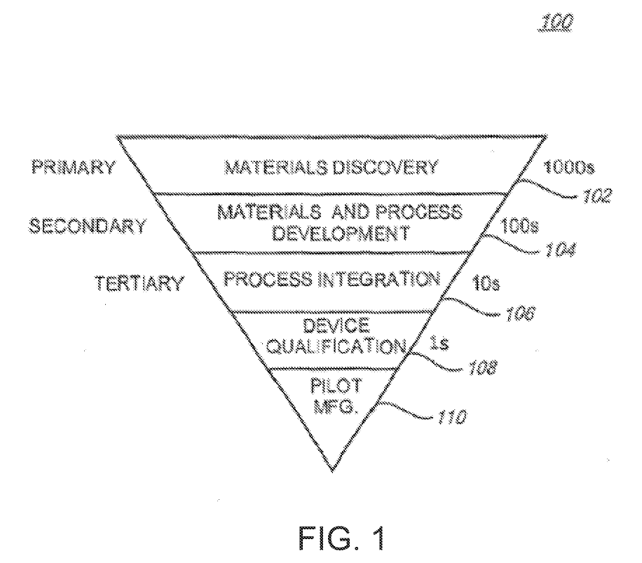

FIG. 1 illustrates a schematic diagram 100 for implementing combinatorial processing and evaluation using primary, secondary, and tertiary screening. The schematic diagram 100 illustrates that the relative number of combinatorial processes run with a group of substrates decreases as certain materials and/or processes are selected. Generally, combinatorial processing includes performing a large number of processes during a primary screen, selecting promising candidates from those processes, performing the selected processing during a secondary screen, selecting promising candidates from the secondary screen for a tertiary screen, and so on. In addition, feedback from later stages to earlier stages can be used to refine the success criteria and provide better screening results.

For example, thousands of materials are evaluated during a materials discovery stage 102. Materials discovery stage 102 is also known as a primary screening stage performed using primary screening techniques. Primary screening techniques may include dividing substrates into coupons and depositing materials using varied processes. The materials are then evaluated, and promising candidates are advanced to the secondary screen, or materials and process development stage 104. Evaluation of the materials is performed using metrology tools such as electronic testers and imaging tools (e.g., microscopes).

The materials and process development stage 104 may evaluate hundreds of materials (i.e., a magnitude smaller than the primary stage) and may focus on the processes used to deposit or develop those materials. Promising materials and processes are again selected, and advanced to the tertiary screen or process integration stage 106 where tens of materials and/or processes and combinations are evaluated. The tertiary screen or process integration stage 106 may focus on integrating the selected processes and materials with other processes and materials.

The most promising materials and processes from the tertiary screen are advanced to device qualification 108. In device qualification, the materials and processes selected are evaluated for high volume manufacturing, which normally is conducted on full substrates within production tools, but need not be conducted in such a manner. The results are evaluated to determine the efficacy of the selected materials and processes. If successful, the use of the screened materials and processes can proceed to pilot manufacturing 110.

The schematic diagram 100 is an example of various techniques that may be used to evaluate and select materials and processes for the development of new materials and processes. The descriptions of primary, secondary, etc. screening and the various stages 102-110 are arbitrary and the stages may overlap, occur out of sequence, be described and be performed in many other ways.

This application benefits from High Productivity Combinatorial (HPC) techniques described in U.S. patent application Ser. No. 11/674,137, filed on Feb. 12, 2007, which is hereby incorporated by reference in its entirety. Portions of the '137 application have been reproduced below to enhance the understanding of the embodiments disclosed herein. The embodiments disclosed enable the application of combinatorial techniques to process sequence integration in order to arrive at a globally optimal sequence of semiconductor manufacturing operations by considering interaction effects between the unit manufacturing operations, the process conditions used to effect such unit manufacturing operations, hardware details used during the processing, as well as material characteristics of components utilized within the unit manufacturing operations. Rather than only considering a series of local optimums, i.e., where the best conditions and materials for each manufacturing unit operation is considered in isolation, the embodiments described below consider effects of interactions introduced due to the multitude of processing operations that are performed and the order in which such multitude of processing operations are performed when fabricating a device. A global optimum sequence order is therefore derived, and as part of this derivation, the unit processes, unit process parameters, and materials used in the unit process operations of the optimum sequence order are also considered.

The embodiments described further analyze a portion or sub-set of the overall process sequence used to manufacture a semiconductor device. Once the subset of the process sequence is identified for analysis, combinatorial process sequence integration testing is performed to optimize the materials, unit processes, hardware details, and process sequence used to build that portion of the device or structure. During the processing of some embodiments described herein, structures are formed on the processed substrate that are equivalent to the structures formed during actual production of the semiconductor device. For example, such structures may include, but would not be limited to, contact layers, buffer layers, absorber layers, or any other series of layers or unit processes that create an intermediate structure found on semiconductor devices. While the combinatorial processing varies certain materials, unit processes, hardware details, or process sequences, the composition or thickness of the layers or structures or the action of the unit process, such as cleaning, surface preparation, deposition, surface treatment, etc. is substantially uniform throughout each discrete region. Furthermore, while different materials or unit processes may be used for corresponding layers or steps in the formation of a structure in different regions of the substrate during the combinatorial processing, the application of each layer or use of a given unit process is substantially consistent or uniform throughout the different regions in which it is intentionally applied. Thus, the processing is uniform within a region (inter-region uniformity) and between regions (intra-region uniformity), as desired. It should be noted that the process can be varied between regions, for example, where a thickness of a layer is varied or a material may be varied between the regions, etc., as desired by the design of the experiment.

The result is a series of regions on the substrate that contain structures or unit process sequences that have been uniformly applied within that region and, as applicable, across different regions. This process uniformity allows comparison of the properties within and across the different regions such that the variations in test results are due to the varied parameters (e.g., materials, unit processes, unit process parameters, hardware details, or process sequences) and not the lack of process uniformity. In the embodiments described herein, the positions of the discrete regions on the substrate can be defined as needed, but are preferably systematized for ease of tooling and design of experimentation. In addition, the number, variants and location of structures within each region are designed to enable valid statistical analysis of the test results within each region and across regions to be performed.

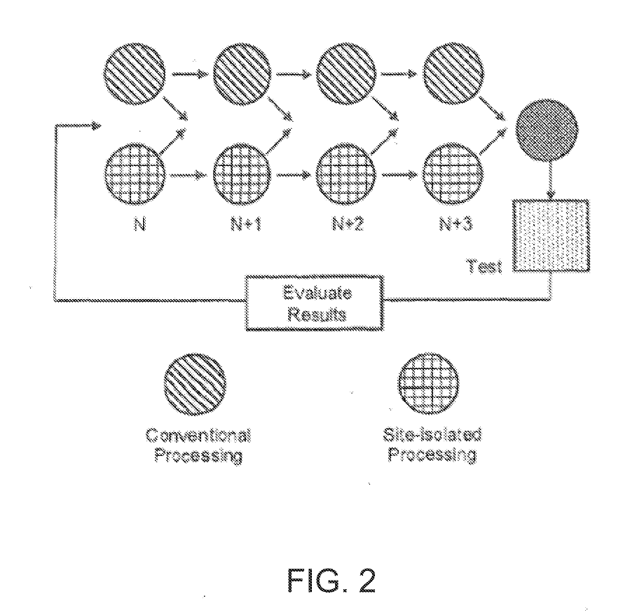

FIG. 2 is a simplified schematic diagram illustrating a general methodology for combinatorial process sequence integration that includes site isolated processing and/or conventional processing in accordance with one embodiment of the invention. In one embodiment, the substrate is initially processed using conventional process N. In one exemplary embodiment, the substrate is then processed using site isolated process N+1. During site isolated processing, an HPC module may be used, such as the HPC module described in U.S. patent application Ser. No. 11/352,077 filed on Feb. 10, 2006. The substrate can then be processed using site isolated process N+2, and thereafter processed using conventional process N+3. Testing is performed and the results are evaluated. The testing can include physical, chemical, acoustic, magnetic, electrical, optical, etc. tests. From this evaluation, a particular process from the various site isolated processes (e.g., from steps N+1 and N+2) may be selected and fixed so that additional combinatorial process sequence integration may be performed using site isolated processing for either process N or N+3. For example, a next process sequence can include processing the substrate using site isolated process N, conventional processing for processes N+1, N+2, and N+3, with testing performed thereafter.

It should be appreciated that various other combinations of conventional and combinatorial processes can be included in the processing sequence with regard to FIG. 2. That is, the combinatorial process sequence integration can be applied to any desired segments and/or portions of an overall process flow. Characterization, including physical, chemical, acoustic, magnetic, electrical, optical, etc. testing, can be performed after each process operation, and/or series of process operations within the process flow as desired. The feedback provided by the testing is used to select certain materials, processes, process conditions, and process sequences and eliminate others. Furthermore, the above flows can be applied to entire monolithic substrates, or portions of monolithic substrates such as coupons.

Under combinatorial processing operations the processing conditions at different regions can be controlled independently. Consequently, process material amounts, reactant species, processing temperatures, processing times, processing pressures, processing flow rates, processing powers, processing reagent compositions, the rates at which the reactions are quenched, deposition order of process materials, process sequence steps, hardware details, etc., can be varied from region to region on the substrate. Thus, for example, when exploring materials, a processing material delivered to a first and second region can be the same or different. If the processing material delivered to the first region is the same as the processing material delivered to the second region, this processing material can be offered to the first and second regions on the substrate at different concentrations. In addition, the material can be deposited under different processing parameters. Parameters which can be varied include, but are not limited to, process material amounts, reactant species, processing temperatures, processing times, processing pressures, processing flow rates, processing powers, processing reagent compositions, the rates at which the reactions are quenched, atmospheres in which the processes are conducted, an order in which materials are deposited, hardware details of the gas distribution assembly, etc. It should be appreciated that these process parameters are exemplary and not meant to be an exhaustive list as other process parameters commonly used in semiconductor manufacturing may be varied.

As mentioned above, within a region, the process conditions are substantially uniform, in contrast to gradient processing techniques which rely on the inherent non-uniformity of the material deposition. That is, the embodiments described herein perform the processing locally in a conventional manner, i.e., substantially consistent and substantially uniform, while globally over the substrate, the materials, processes, and process sequences may vary. Thus, the testing will find optimums without interference from process variation differences between processes that are meant to be the same. It should be appreciated that a region may be adjacent to another region in one embodiment or the regions may be isolated and, therefore, non-overlapping. When the regions are adjacent, there may be a slight overlap wherein the materials or precise process interactions are not known, however, a portion of the regions, normally at least 50% or more of the area, is uniform and all testing occurs within that region. Further, the potential overlap is only allowed with material of processes that will not adversely affect the result of the tests. Both types of regions are referred to herein as regions or discrete regions.

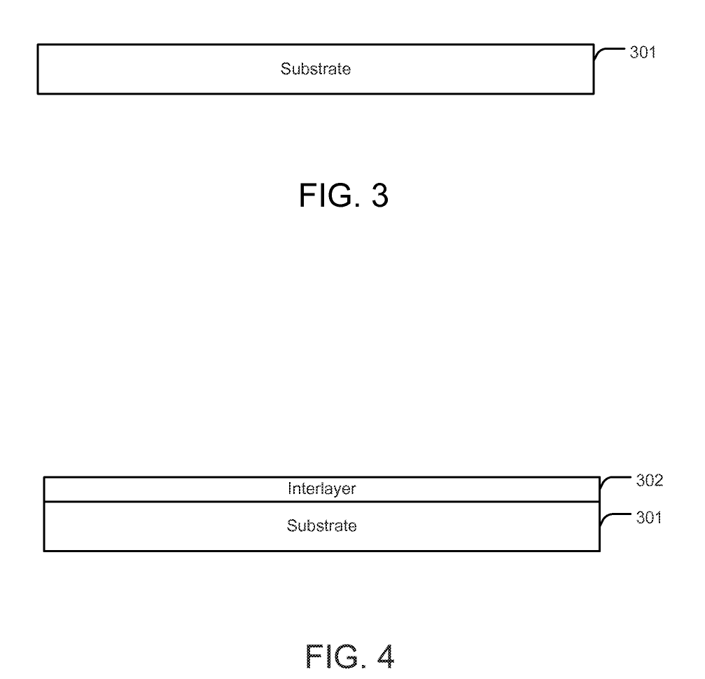

An exemplary method of creating a MOS-based device, which may be integrated with any of the combinatorial processing techniques described above, is illustrated in FIGS. 3-8. As illustrated in FIG. 3, an appropriate substrate 301 or portion thereof may be prepared for further processing. An appropriate substrate may include a silicon wafer or wafer of another appropriate semiconductor material. Preparation may include surface preparation of one or more areas or regions, on an outer surface of a substrate, which may include cleaning, milling, abrading, or any suitable preparation technique. Upon preparation of the surface or any portion thereof, the method may include forming any Interlayer (IL) 302 on the substrate 301, as illustrated in FIG. 4. The IL 302 may be an ultra-thin interlayer in some embodiments. The IL 302 may be composed of any suitable material, including high-k dielectric materials including but not limited to Al₂O₃. The IL 302 may be within the order of about 5-15 A in total thickness in some embodiments. Thickness and composition of the IL 302 may be optimized through a combinatorial process as described above.

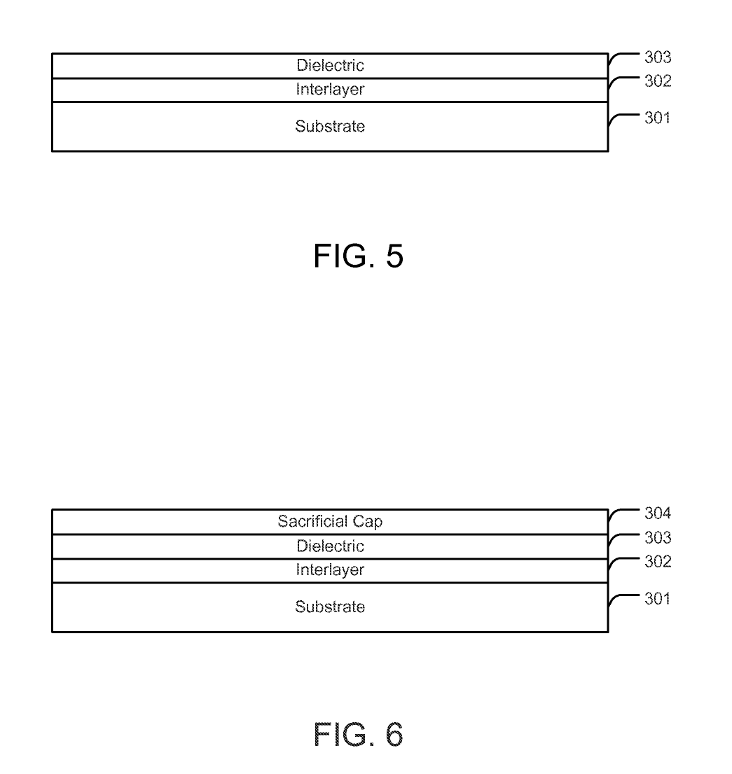

After forming the IL 302, the method may include forming a dielectric layer 303 on a surface of the IL 302, as illustrated in FIG. 5. The dielectric layer 303 may be formed of any suitable material, including high-k dielectric or oxide materials including but not limited to, Hafnium dioxide (Hafnia—HfO₂), Zirconium di-oxide (Zirconia—ZrO₂), Titanium oxide (TiOₓ), Tantalum Oxide (TaOₓ), etc. The dielectric layer 303 may be within any suitable or desired order of total thickness. Thickness and composition of the dielectric layer 303 may be optimized through a combinatorial process as described above. Furthermore, the IL 302 and dielectric layer 303 may be termed a dielectric stack or simply dielectric herein for brevity of discussion.

After forming the dielectric later 303, the method includes forming a sacrificial cap layer 304 on the dielectric layer 303, as illustrated in FIG. 6. The sacrificial cap layer 304 may be formed of a material with a relatively low work function. According to exemplary embodiments, a relatively low work function is a work function of about 4.3 eV or less. Therefore, any material with a relatively low work function may be suitable for formation of the sacrificial cap layer 304. The exact type, composition, thickness, and other attributes of the material may be optimized through the combinatorial techniques described above. Accordingly, exemplary embodiments should not be limited to merely one form or type of sacrificial cap layer 304, but should be interpreted to comprise all suitable equivalents and similar constructs. Exemplary materials for the sacrificial cap layer having a relatively low work function include, but not limited to Titanium, Tantalum, Hafnium, Titanium Carbide, Tantalum Carbide.

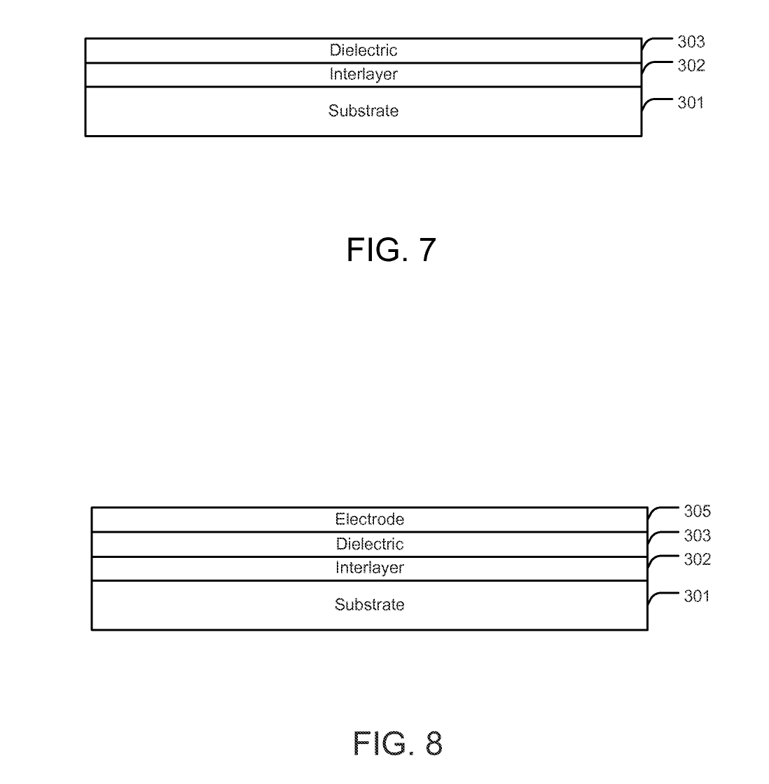

After forming the sacrificial cap layer 304, the method further includes processing the substrate (e.g., to alter its properties via doping or other processing) and removing the sacrificial cap layer after the processing, as illustrated in FIG. 7. The processing may include annealing or other suitable processing at temperatures up to and around 1050-1100 Celsius. The gases during annealing may include forming gas (N₂/H₂) anneal (FGA), Nitrogen (N₂) anneal, Argon hydrogen anneal (Ar/H₂), etc. Typical temperatures for the annealing may range from 300-500 Celsius for 10-30 minutes in some embodiments. The removal of the sacrificial cap layer may include a wet or plasma etching process. It is thermodynamically more favorable for a high work-function (WF) layer, such as Titanium nitride, to extract Oxygen from the underlying dielectric stack, as opposed to a lower WF layer. Oxygen extraction from the dielectric stack introduces positively charged Oxygen vacancies, which are responsible for V_{fb} roll-off. Furthermore, Oxygen vacancy generation is exacerbated for higher temperatures. Thus, the combination of a high WF layer, on top of the dielectric stack, followed by high temperature processing steps, results in significant V_{fb} roll-off. The low WF layer, on the other hand, has a weaker tendency to extract Oxygen from the underlying dielectric stack compared to a high WF layer. Thus, the number of oxygen vacancies migrating from the dielectric layer 303 to the IL 302, even for Interlayer thicknesses within an order of magnitude of the diffusion length of an oxygen atom, will be significantly reduced for a low WF layer, compared to a high WF layer. The relatively low work function of the sacrificial cap layer 304 provides this advantage over the high WF layer even in subsequent high-temperature processing steps. As such, additional high-temperature steps may be used during processing to further enhance device capability while reducing the drawbacks associated with oxygen vacancies. Moreover, complementary dielectric stack tuning steps, like LTOA, ion implantation of the high-k layer, may also be integrated to further enhance the properties of MOS-based devices.

After subsequent processing steps and removal of the sacrificial cap layer 304, the method includes forming an electrode 305 on the dielectric layer 303. The electrode 305 may be formed of a material with a relatively high work function in some embodiments. According to exemplary embodiments, a relatively high work function is a work function of about, 4.7-5 eV or more. Exemplary materials include but not limited to Titanium Nitride, Tantalum nitride, Platinum, Palladium, and Gold. In other embodiments, a relatively low work function layer may be utilized for electrode 305 after the sacrificial layer is removed. In some embodiments, the sacrificial layer described above may serve as the work function layer for N-type metal oxide semiconductor (NMOS) application/structure. Hence, in this embodiment the sacrificial layer wouldn't be etched after the annealing. It should be appreciated that a high work function layer is used for P-type metal oxide semiconductor (PMOS) application/structure, whereas, a low work function layer is used for an NMOS application/structure.

As described above, the sacrificial cap layer provides for a reduced occurrence of oxygen vacancies within the stack formed of the dielectric 303 and IL 302. As a result of the reduced occurrence of oxygen vacancies at IL 302, the flatband voltage of the stack remains stable and will not shift to a negative value, which may be referred to as flat band voltage roll off, and which is typically a result of the oxygen vacancies migrating to IL 302. As is generally known, the flatband voltage is a component of the threshold voltage. It should be appreciated that the sacrificial cap layer 304 may be used in addition to conventional methodologies of preserving a flatband voltage to further enhance benefits of the use of the sacrificial cap layer. Conventional techniques include doping the high-k dielectric with fluorine, lanthanum, aluminum, and low temperature oxygen annealing which may be used alternative to or in combination with the high-temperature processes noted above. Moreover, the processes described above may include a combinatorial process to more efficiently discover optimal work function values for both the sacrificial cap layer 304 and electrode 305. Thus, the processes described above may include combinatorial processing of site isolated regions of a substrate to optimize at least one attribute of sacrificial cap layers formed on the remaining portions. The at least one attribute may include thickness or composition. It should be appreciated that attributes of the electrode may be optimized in some embodiments through combinatorial processing techniques.

When compared to existing methods, the embodiments described can provide MOS-based devices with increased mobility and stable flatband voltages with very limited changes to existing process flow. The corresponding structures, materials, acts, and equivalents of all means plus function elements in any claims below are intended to include any structure, material, or acts for performing the function in combination with other claim elements as specifically claimed.

Those skilled in the art will appreciate that many modifications to the exemplary embodiments are possible without departing from the spirit and scope of the present invention. In addition, it is possible to use some of the features of the present invention without the corresponding use of the other features. Accordingly, the foregoing description of the exemplary embodiments is provided for the purpose of illustrating the principles of the present invention, and not in limitation thereof, since the scope of the present invention is defined solely by the appended claims.

1. A method of providing a processed dielectric stack, comprising:
forming a first dielectric layer on a substrate;
depositing a second dielectric layer on the first layer to form a first dielectric stack;
forming a third layer over the first dielectric stack;
processing the substrate to alter properties of the first dielectric stack; and
removing the third layer to provide a processed dielectric stack;
wherein the processed dielectric stack comprises the second dielectric layer overlying the first dielectric layer.

2. The method of claim 1, wherein the third layer comprises a material with a work function less than about 4.3 eV.

3. The method of claim 1, wherein processing the substrate includes a high-temperature process.

4. The method of claim 3, wherein the high-temperature process includes at least one annealing process.

5. The method of claim 1, wherein processing the substrate includes a low temperature oxygen annealing process.

6. The method of claim 1, wherein processing the substrate includes an ion implantation process.

7. The method of claim 1, further comprising:
forming an electrode on the processed dielectric stack after removing the third layer.

8. The method of claim 7, wherein the electrode comprises a material with a work function greater than about 4.7 eV.

9. The method of claim 7, wherein the electrode comprises a material with a work function less than 4.3 eV.

10. The method of claim 1, further comprising:
preparing a surface of the substrate prior to forming the second layer.

11. The method of claim 1, wherein removing the third layer comprises an etching process.

12. The method of claim 11, wherein the etching process comprises a wet-etching process.

13. The method of claim 11, wherein the etching process comprises a plasma etching process.

14. The method of claim 1, wherein the substrate is processed in a combinatorial manner to efficiently discover optimal values of a third layer work function value or of a third layer thickness.

15. A method, comprising:
preparing a substrate for combinatorial processing;
depositing a first layer on a first site isolated region of the substrate;
depositing a second layer on the first layer;
depositing a third layer over the second layer;
processing the substrate to alter properties of at least one of the deposited layers; and removing the third layer.

16. The method of claim 15, further comprising:
combinatorial processing of remaining site isolated regions of the substrate by repeating each operation for a different region of the substrate.

17. The method of claim 15, wherein the third layer comprises a material with a work function less than about 4.3 eV.

18. The method of claim 15 further comprising forming an electrode on the deposited layers.

19. The method of claim 18, further comprising:
combinatorial processing of the remaining site isolated regions of the substrate to optimize at least one attribute of electrodes formed on the deposited layers.

20. The method of claim 19, wherein the electrode comprises a material with a work function greater than 4.7 eV.

21. The method of claim 19, wherein the electrode comprises a material with a work function less than 4.3 eV.
